(19) United States
(12) Patent Application Publication
(10) Pub. No.: US 2009/0149034 A1
(43) Pub. Date: Jun. 11, 2009

(54) SEMICONDUCTOR MODULE AND METHOD OF MANUFACTURING THE SAME

(75) Inventors: Ryosuke USUI, Ichinomiya-shi (JP); Hideki Mizuhara, Bisai-shi (JP); Takeshi Nakamura, Sawa-gun (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD., Osaka (JP)

(21) Appl. No.: 12/335,150

(22) Filed: Dec. 15, 2008

Related U.S. Application Data
(62) Division of application No. 10/813,629, filed on Mar. 31, 2004, now abandoned.

(30) Foreign Application Priority Data
Mar. 31, 2003 (JP) 2003-093324
Mar. 9, 2004 (JP) 2004-065243
Mar. 24, 2004 (JP) 2004-086770

(51) Int. Cl. H01L 21/26

(52) U.S. Cl. 438/798; 257/E21.328

(57) ABSTRACT

In a semiconductor module, adhesion between an insulating base material and an insulator provided on the insulating base material, for example a sealing resin of the semiconductor element, is to be improved.

A plurality of interconnect layers, each including an interlayer dielectric film 405 and a copper interconnect 407, is stacked and a solder resist layer 408 is formed on an uppermost layer. Elements 410a and 410b are formed on a surface of the solder resist layer 408. The elements 410a and 410b are molded in a molding resin 415. The surface of the solder resist layer 408 is modified by plasma processing under a specific condition so that minute projections are formed thereon. Such surface of the solder resist layer 408 is processed such that a value of y/x becomes not less than 0.4, where x represents a detected intensity at a binding energy of 284.5 eV and y represents a detected intensity at a binding energy of 286 eV, by an X-ray photoelectric spectroscopy spectrum.

This application is based on Japanese patent application NO. 2003-093324 and Japanese patent application NO. 2004-086770, the content of which is incorporated hereinto by reference.

### BACKGROUND OF THE INVENTION

1. Field of the Invention

The present invention relates to a semiconductor module provided with a semiconductor element and so on to be bonded to a circuit board etc., and to a method of manufacturing such semiconductor module.

2. Description of the Related Art

The ongoing progress in performance of portable electronic apparatuses such as a mobile phone, PDA, DVC, DSC, etc., which has been achieved under a constant pressure from the market to make such products smaller in dimensions and lighter in weight, has concurrently generated the increasing demand for a more highly integrated system LSI to meet such market requirement. Likewise, the market has also been requesting ease and simplicity in use from these electronic apparatuses, which in turn has been promoting the progress of an LSI in its functions and performance. Accordingly, while the number of I/Os has been increasing with the progress in integration grade of an LSI, a chip package itself has also been required to be smaller, resulting in a strong demand for development of a semiconductor package suitable for mounting semiconductor components in high concentration on a circuit board, to satisfy the requirements in both ways. In an attempt to fulfill such requirements, various packaging techniques called a “CSP (Chip Size Package)” have been proposed.

One of well-known examples of such packages is the BGA (Ball Grid Array). The BGA is made through mounting a semiconductor element on a package substrate, resin molding the substrate and placing solder balls according to an area shape on the other face of the substrate so that the solder balls work as an external terminal. Since the mounting area can be formed in a plane in a BGA process, it is relatively easy to miniaturize a package. Besides, when employing the BGA process limitation due to a narrow pitch is not imposed when designing a circuit board, which eliminates need of employing a high-precision packaging technique, therefore the mounting cost as a whole can be reduced despite using a rather expensive package.

FIG. 1 shows a structure outline of a popular BGA. The BGA 100 is constituted of a glass epoxy substrate 106 on which an LSI chip 102 is mounted via an adhesion layer 108. The LSI chip 102 is molded in a sealing resin 110. The LSI chip 102 and the glass epoxy substrate 106 are electrically connected via a metal interconnect line 104. Solder balls 112 are aligned in an array on a rear face of the glass epoxy substrate 106. Via these solder balls 112, the BGA 100 is mounted on a printed circuit board.

JP-A laid open No. 2002-94247 cited below refers to another example of the CSP. JP-A laid open No. 2002-94247 discloses a system in package including a high-frequency LSI. This package is constituted of a base substrate provided thereon with a multilayer interconnect structure, on which a semiconductor element provided with the high-frequency LSI and so forth is formed. The multilayer interconnect structure consists of layers such as a core substrate, a copper foil with a resin, etc.

However, it has been difficult to satisfy with such conventional CSP the current high-level requirements for reduction in size and thickness as well as in weight of portable electronic apparatuses. An important reason is that a conventional CSP includes a substrate to carry a chip thereon. Because of the existence of the substrate, the entire package inevitably becomes thick, which naturally constitutes a critical disturbance against the attempt of reducing size, thickness and weight, and also against improvement of heat dissipation.

In a package such as the foregoing BGA etc., it is essential to secure sufficient adhesion between a substrate and a sealing resin layer for sealing an element therein, and the perfection in interface adhesion is more strictly required especially from such a semiconductor module as an ISB to be subsequently referred to, since it is not provided with a substrate.

### SUMMARY OF THE INVENTION

The present invention has been conceived in view of the foregoing situation, with an object to improve adhesion between an insulating base material and an insulator such as a sealing resin of a semiconductor element or an adhesive formed on the insulating base material, in a module including a semiconductor module.

According to the present invention, there is provided a semiconductor module comprising an insulating base material provided with a conductor circuit; a semiconductor element formed on the insulating base material; and an insulator disposed in contact with the insulating base material and the semiconductor element; wherein the insulating base material is provided with minute projections on a surface thereof that is in contact with the insulator.

In the present invention, the term of “semiconductor element” is to be construed as including a semiconductor chip, a chip resistance, a chip condenser, a chip conductor, and so forth.

Such semiconductor module offers excellent adhesion at an interface between an insulating base material and an insulator, because of the minute projections formed on a surface of the insulating base material that is in contact with the insulator.

Also, the insulator may be a sealing resin for sealing a semiconductor element therein or an adhesive provided between the semiconductor element and the insulating base material.

Also, a plurality of crater-shaped recesses may be formed on a surface of the insulating base material that is in contact with the insulator, and a diameter of the crater-shaped recess may be in a range of 0.1 μm to 1 μm.

Such semiconductor module offers excellent adhesion at an interface between an insulating base material and an insulator, because of the plurality of crater-shaped recesses having a diameter in a range of 0.1 μm to 1 μm formed in addition to the minute projections on the insulating base material surface in contact with the insulator.

It is preferable that the minute projections include a plurality of projections of 1 nm to 20 nm in average diameter. Also, a number density of the projections is preferably not less than 0.5×10³ μm⁻², more preferably in a range of 0.8×10³ μm⁻² to 2.0×10³ μm⁻². Particularly, a range of 1.6×10³ μm⁻² to 2.0×10³ μm⁻² is most preferable. With such minute projections, the adhesion at an interface between the insulating base material and the insulator can be more prominently improved.

According to another aspect of the present invention, there is provided a semiconductor module comprising an insulating base material provided with a conductor circuit; a semiconductor element formed on the insulating base material; and an insulator disposed in contact with the insulating base material and the semiconductor element; wherein a surface of the insulating base material in contact with the insulator is constituted essentially of an epoxy resin; and a value of y/x is not less than 0.4, where x represents a detected intensity at a binding energy of 284.5 eV and y represents a detected intensity at a binding energy of 286 eV, by an X-ray photoelectric spectroscopy spectrum in the proximity of a surface of the insulating base material that is in contact with the insulator.

Here, the binding energy of 286 eV is imputed to a C1s electron that forms a C═O bond. On the other hand, the binding energy of 284.5 eV is imputed to a C1s electron that forms a C—O bond or a C—N bond. By adjusting such that a ratio of these electrons satisfy the foregoing condition, the adhesion at an interface between the insulating base material and the insulator can be significantly improved. By the way, an upper limit of the y/x value may be set at 3, for example.

According to another aspect of the present invention, there is provided a semiconductor module comprising an insulating base material provided with a conductor circuit; a semiconductor element formed on the insulating base material; and an insulator disposed in contact with the insulating base material and the semiconductor element; wherein an exposed region of the insulating base material in contact with the insulator makes a contact angle of 30 degrees to 120 degrees with respect to pure water.

As a result of employing a resin material that makes such a contact angle, the adhesion at an interface between the insulating base material and the insulator can be significantly improved.

The above semiconductor module can be obtained through, for example, plasma processing under a specific condition where a bias is not applied.

According to another aspect of the present invention, there is provided a semiconductor module comprising an insulating base material provided with a conductor circuit; a semiconductor element formed on the insulating base material; and an insulator disposed in contact with the insulating base material and the semiconductor element; wherein the insulating base material is constituted essentially of a photopolymerizable thermosetting resin containing a polyfunctional oxetane compound or an epoxy compound.

By employing a photopolymerizable thermosetting resin containing a polyfunctional oxetane compound or an epoxy compound as the insulating base material of the semiconductor module, it becomes possible to carry out a patterning, and also the adhesion at an interface between the insulating base material and the insulator can be significantly improved.

According to the present invention, there is provided a module comprising a base material; an element formed on the base material; and an insulator disposed in contact with the base material and the element; wherein the base material is provided with minute projections on a surface thereof that is in contact with the insulator.

Such module offers excellent adhesion at an interface between a base material and an insulator, because of the minute projections formed on a surface of the base material that is in contact with the insulator.

Also, a plurality of crater-shaped recesses may be formed on the base material surface that is in contact with the insulator, and the minute projections may include a plurality of projections of 1 nm to 20 nm in average diameter.

Further, according to the present invention, there is provided a method of manufacturing the foregoing semiconductor module comprising applying plasma processing with a plasma gas containing an inert gas to a surface of the insulating base material provided with a conductor circuit without applying a bias to the insulating base material; and forming a semiconductor element and an insulator in contact with the semiconductor element on the insulating base material.

Executing the plasma processing in such manner permits stabilized production of a semiconductor module that offers excellent adhesion at an interface between the insulating base material and the insulator. By the way, the term of “bias” used herein does not include a self bias of the substrate.

According to another aspect of the present invention, there is provided a method of manufacturing the foregoing module comprising applying plasma processing with a plasma gas containing an inert gas to a surface of the base material without applying a bias to the base material; and forming an element and an insulator in contact with the element on the base material.

Executing the plasma processing in such manner permits stabilized production of a module that offers excellent adhesion at an interface between the base material and the insulator. By the way, the term of “bias” used herein does not include a self bias of the substrate.

The present invention becomes more effective by employing a bare chip as the semiconductor element, and a sealing resin for sealing the bare chip therein as the insulator. While such constitution permits achieving a thin and lightweight package, it is prone to incur faulty adhesion between an insulating base material and a sealing resin, however the present invention effectively solves such problem.

In the present invention, the “conductor circuit” means a circuit provided with a copper interconnect etc. formed inside or on a surface of a base material. The “insulating base material” herein means an insulative base material supporting a semiconductor element and a conductor circuit connected thereto, and the “insulator” means for example a sealing resin for sealing therein a semiconductor element provided on an insulating base material, or an insulating layer or an adhesive, etc. disposed between an insulating base material and a semiconductor element.

According to the present invention, in a module including a semiconductor module the adhesion between an insulating base material and an insulator provided thereon, such as a sealing resin of a semiconductor element, can be improved.

### BRIEF DESCRIPTION OF THE DRAWINGS

FIG. 1 is a schematic perspective view showing a structure of a BGA;

FIG. 2 is a schematic perspective view showing a structure of an ISB (trademark);

FIGS. 3A and 3B are plans views showing a manufacturing process of the BGA and the ISB(trademark);

FIGS. 4A and 4B are schematic cross-sectional views showing a structure of a semiconductor module according to a first embodiment of the present invention;

FIGS. 5A to 5C are schematic cross-sectional views showing a manufacturing process of a semiconductor module according to the first embodiment;

FIGS. 6A and 6B are schematic cross-sectional views showing a manufacturing process of a semiconductor module according to the first embodiment;

FIGS. 7A and 7B are schematic cross-sectional views showing a manufacturing process of a semiconductor module according to the first embodiment;

FIG. 8 is a schematic cross-sectional view showing a manufacturing process of a semiconductor module according to a second embodiment;

FIGS. 9A and 9B are schematic cross-sectional views showing a manufacturing process of a semiconductor module according to the second embodiment;

FIGS. 10A and 10B are schematic cross-sectional views showing a structure of a semiconductor module according to the second embodiment;

FIG. 11 shows a film surface viewed after plasma processing through a scanning electronic microscope;

FIG. 12 shows a film surface viewed after plasma processing through a scanning electronic microscope;

FIG. 13 shows a film surface viewed before plasma processing through a scanning electronic microscope;

FIG. 14 is a graph showing a result of X-ray photoelectron spectroscopy of a film surface after plasma processing;

FIG. 15 is a schematic side view showing a structure of a semiconductor module according to a third embodiment;

FIG. 16 shows a film surface viewed after plasma processing through a scanning electronic microscope;

FIG. 17 shows a film surface viewed after plasma processing through a scanning electronic microscope;

FIG. 18 shows a film surface viewed before plasma processing through a scanning electronic microscope; and

FIG. 19 is a graph showing a result of X-ray photoelectron spectroscopy of a film surface after plasma processing.

### DETAILED DESCRIPTION OF THE INVENTION

The embodiments of the present invention will now be described hereunder, prior to which an ISB structure employed in the following embodiments will be first described. The ISB (Integrated System in Board; trademark) is a unique package developed by the present applicant. The ISB is a unique coreless system in package that does not employ a core (base material) for supporting circuit components thereon despite having an interconnect pattern made of copper, when packaging electronic components provided with a semiconductor bare chip as a primary component. An example of such system in package is described in JP-A laid No. 2002-110717.

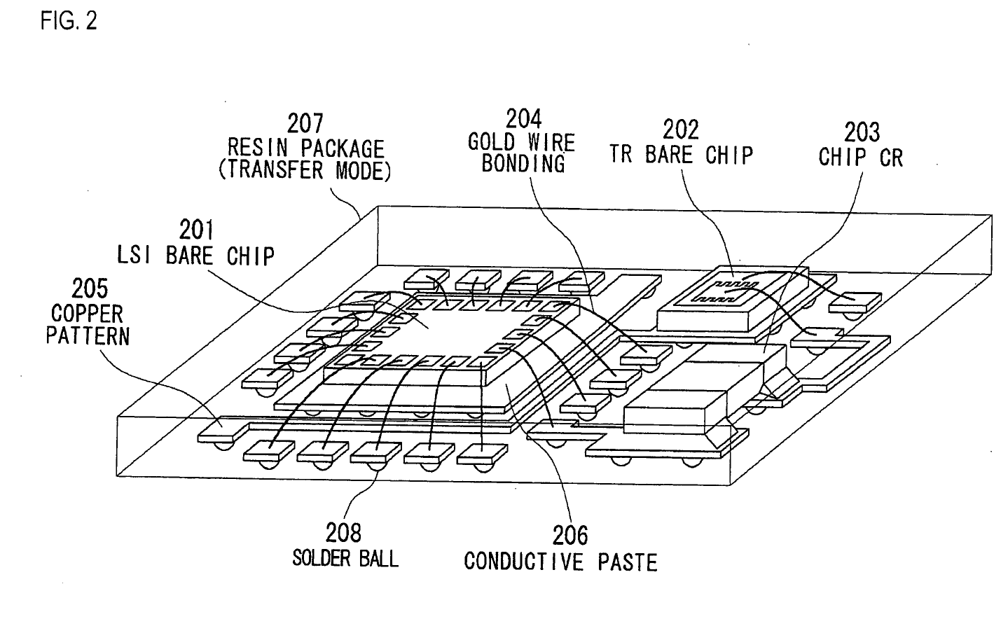

FIG. 2 shows a structure outline of an ISB. Though FIG. 2 only shows a single wiring layer for the sake of explicitness, actually a plurality of wiring layers is stacked. The ISB is provided with an LSI bare chip 201, a Tr bare chip 202 and a chip CR 203 connected via a wiring constituted of a copper pattern 205. The LSI bare chip 201 is electrically connected via a gold wire bonding 204 with a lead electrode or a wiring. On a rear surface of the lead electrode or the wiring, solder balls 208 are formed. A conductive paste 206 is provided right under the LSI bare chip 201, via which the ISB is mounted on the printed circuit board. An entirety of the ISB is sealed in a resin package 207 made of an epoxy resin or the like.

Such package offers the following advantages.
(i) Since coreless packaging can be executed, a transistor, an IC or an LSI can be made smaller and thinner.
(ii) Since it is possible to forma a circuit and build a package including everything from a transistor to a system LSI, and even a chip type condenser or resistance, a high-grade SIP (System in Package) can be accomplished.
(iii) Since semiconductor elements currently available can be combined, a system LSI can be developed in a short period.
(iv) Since a semiconductor bare chip is directly mounted on a copper material disposed right the chip, efficient heat dissipation can be achieved.
(v) Since a circuit wiring is made of copper without using a core material, a low dielectric constant circuit can be constituted and excellent characteristics can be achieved in high-speed data transmission or in a high-frequency circuit.
(vi) Since an electrode is embedded inside the package, particle contamination due to the electrode material can be restrained.
(vii) The package size can be freely determined and an amount of waste per piece is only one tenth of a 64-pin SQFP package, which leads to alleviation of environmental impact.
(viii) A system based on a new concept of a circuit board implemented with actual functions can be constituted, advancing from a printed circuit board simply for mounting components thereon.
(ix) Since pattern designing of the ISB is as easy as designing a printed circuit board, an engineer in an assembly manufacturer can design by him/herself.

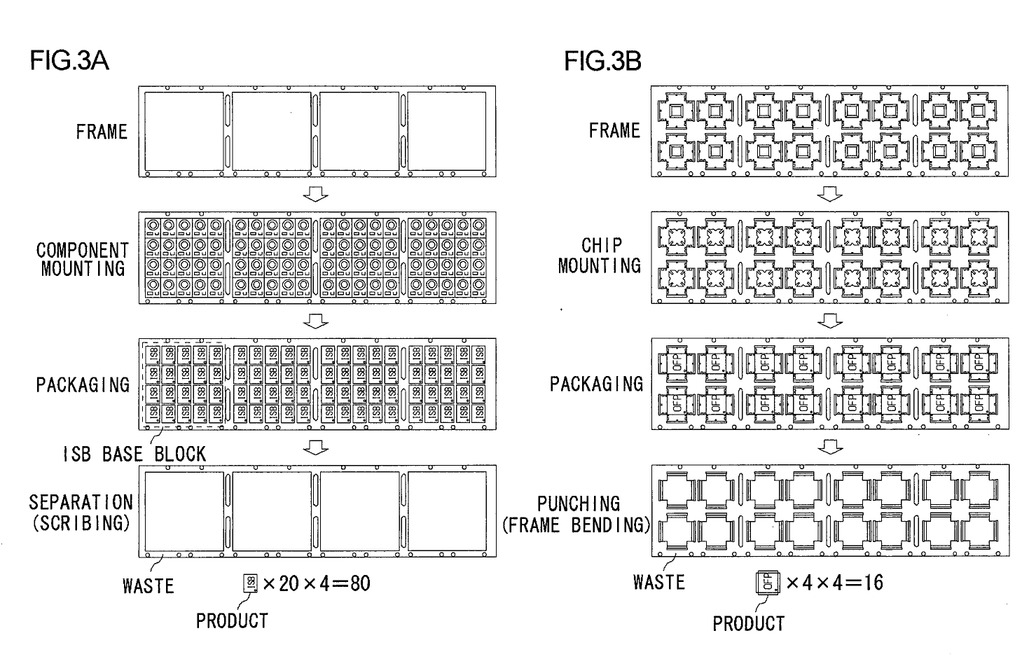

Now the advantage that the ISB can offer in a manufacturing process will be described. FIGS. 3A and 3B constitute a comparison flowchart of a manufacturing process of a conventional CSP and the ISB according to the present invention respectively. FIG. 3B shows a manufacturing process of a conventional CSP. Firstly frames are formed on a base circuit board and a chip is mounted on a predetermined element forming region in each frame. Then a package of a thermosetting resin is provided to each element and punching is carried out on each of such elements using a die. At the punching process, which is the final step, the molding resin and the base board are cut off at a time; therefore roughness of the cut surface may incur a problem. Besides, this process is disadvantageous from the viewpoint of environmental impact, because a great deal of wastes is produced through the punching process.

On the other hand, FIG. 3A shows a manufacturing process of the ISB. Firstly frames are provided on a metal foil, and a wiring pattern is formed in each module forming region, on which a circuit element such as an LSI is mounted. Then each module is packaged and dicing is carried out along the scribed regions to obtain finished products. During such process the metal foil serving as the base is removed between the packaging and scribing steps; therefore it is only the resin layer that is cut at the dicing step in the scribing process. Consequently, roughness of the cut surface can be restrained and accuracy in dicing operation can be improved.

### First Embodiment

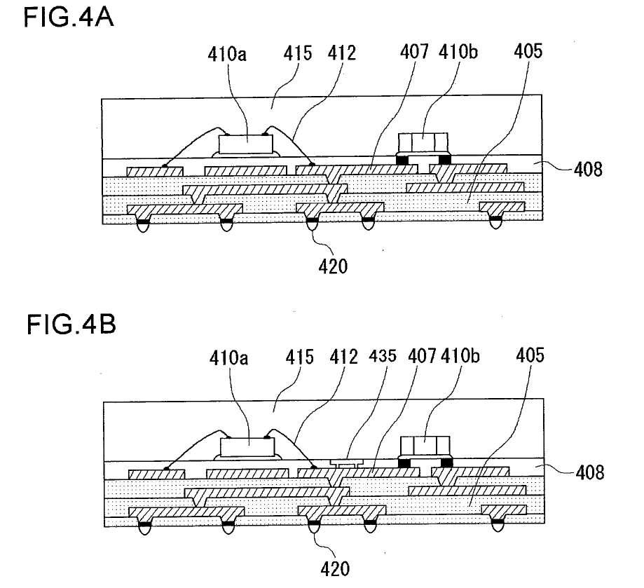

Now preferable embodiments of the present invention will be described referring to a semiconductor module having the foregoing ISB structure. FIGS. 4A and 4B are schematic cross-sectional views showing a semiconductor module according to this embodiment. This semiconductor module is constituted of a multilayer interconnect structure including a plurality of interconnect layers respectively consisting of an interlayer dielectric film 405 and a copper interconnect 407 and provided with a solder resist layer 408 on an uppermost layer thereof, and of an element 410a and 410b formed on a surface of the solder resist layer 408. On a rear surface of the multilayer interconnect structure, solder balls 420 are provided. The elements 410a and 410b are molded in a molding resin 415. Referring to FIG. 4B, a dummy interconnect 435 made of a metal material is further provided to the structure of FIG. 4A. The dummy interconnect 435 serves to improve adhesion between the multilayer interconnect structure and the molding resin 415.

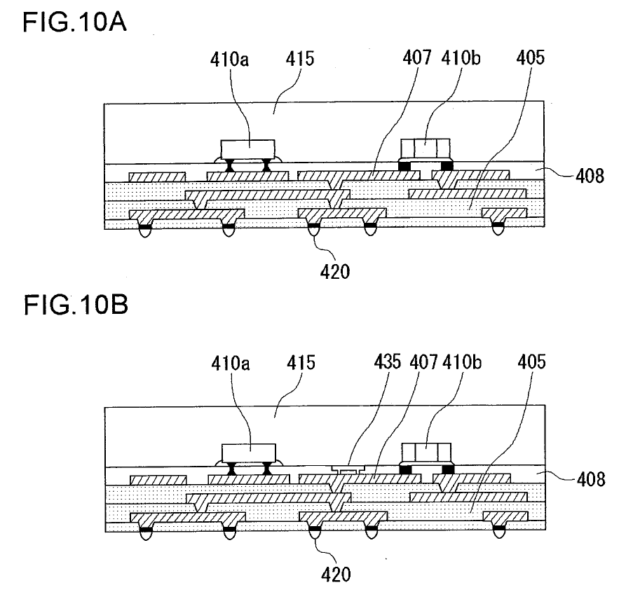

Referring to a mounting method of the element 410a, while FIGS. 4A and 4B represent a wire bonding method it is also possible to adopt a flip-chip mounting by which the element 410a is disposed face down, as shown in FIGS. 10A and 10B.

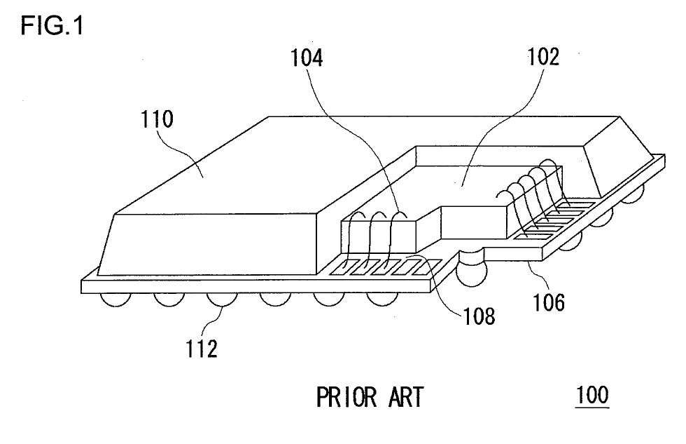

In the conventional semiconductor module shown in FIG. 1, the LSI chip 102 is constituted of a bare chip sealed in by a sealing resin. By contrast, in the semiconductor module of FIGS. 4A and 4B, the element 410a is a bare chip not sealed in by a sealing resin. Accordingly, it is essential to take an efficient measure against moisture. In case where delamination takes place at an interface between the molding resin 415 and the multilayer interconnect structure, moisture can intrude through such point during for example a soldering step, and the bare chip may be directly exposed to moisture. This results in significant degradation of the chip performance. As such, it is an essential technical issue in a semiconductor module having an ISB structure as shown in FIGS. 4A and 4B, to upgrade the adhesion at the mentioned interface, to thereby sufficiently restrain moisture penetration.

With an object to solve the foregoing problem, plasma processing under a specific condition has been adopted in this embodiment, to modify a surface of the solder resist layer 408. Specifically, minute projections have been formed on a surface of the solder resist layer 408 that is to be in contact with the molding resin 415. Also, such surface of the solder resist layer 408 has been processed such that a value of y/x becomes not less than 0.4, where x represents a detected intensity at a binding energy of 284.5 eV and y represents a detected intensity at a binding energy of 286 eV in an X-ray photoelectric spectroscopy spectrum.

Further, an exposed region of the solder resist layer 408 that is to make contact with the molding resin 415 has been processed so as to form a contact angle of 30 degrees to 120 degrees with respect to pure water.

For constituting the solder resist layer 408, interlayer dielectric film 405 and the molding resin 415, a resin material can be independently selected for the respective items, for example out of a melamine derivative such as a BT resin, or a thermosetting resin such as a liquid crystal polymer, epoxy resin, PPE resin, polyimide resin, fluorine resin, phenol resin, polyamide-bis-maleimide, etc. Among the foregoing, a liquid crystal polymer, epoxy resin, or a melamine derivative such as a BT resin is preferably employed because of excellent high-frequency characteristics. A filler or an additive may be added to such resin as the case may be.

For constituting an insulating base material according to the present invention, it is preferable to employ an epoxy resin, a BT resin, or a liquid crystal polymer. Employing such resin facilitates production of a semiconductor module having excellent high-frequency characteristics and high reliability.

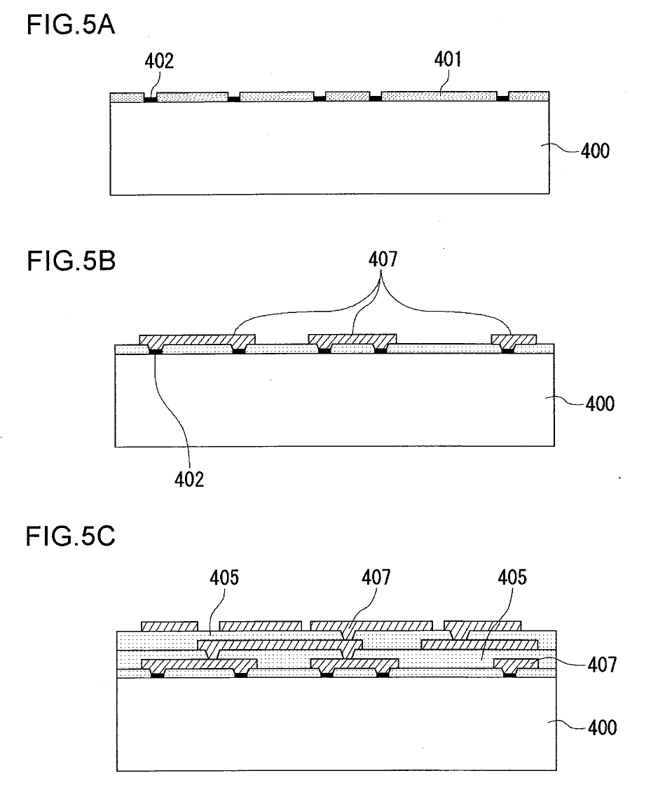

A method of manufacturing the semiconductor module shown in FIG. 4A will now be described referring to FIGS. 5A to 7B. Firstly a conductive coating 402 is selectively formed on a predetermined region of a surface of a metal foil 400 as shown in FIG. 5A. Practically, after coating the metal foil 400 with a photoresist 401, electrolytic plating is performed to form the conductive coating 402 on an exposed surface of the metal foil 400. The conductive coating 402 may be formed in a thickness of for example 1 to 10 μm. To form the conductive coating 402 it is preferable to employ gold or silver which is highly adhesive with a brazing material such as a solder, because the conductive coating 402 is to serve as a rear electrode of the semiconductor module when the module is completed. Thereafter, the photoresist 401 is removed.

Thereafter, a first interconnect pattern layer is formed on the metal foil 400 as shown in FIG. 5B. Firstly chemical polishing is executed on a surface of the metal foil 400 for cleaning and surface coarsening. Then a thermosetting resin is applied so as to cover all over the conductive coating 402 on the metal foil 400, and heat curing is executed to form a film having a plane surface. A via hole of approx. 100 μm in diameter and deep enough to reach the conductive coating 402 is then formed in such film. To form the via hole, laser processing is employed in this embodiment, while it is also possible to perform mechanical processing, chemical etching utilizing a chemical solution, or dry etching utilizing plasma. Then after removing etching residue by laser irradiation, a copper plated layer is formed all over so as to fill the via hole. Thereafter etching is performed on the copper plated layer utilizing a photoresist as the mask, to form an interconnect 407 made of copper. To be more detailed, for example a chemical etching solution may be sprayed over a portion exposed through the photoresist to etch-remove unnecessary copper foil, thus to form an interconnect pattern.

Through repetitions of the foregoing steps of forming the interlayer dielectric film 405, forming the via hole, forming the copper plated layer and patterning on the copper plated layer, a multilayer interconnect structure including stacked interconnect layers respectively constituted of the interconnect 407 and the interlayer dielectric film 405 can be formed as shown in FIG. 5C.

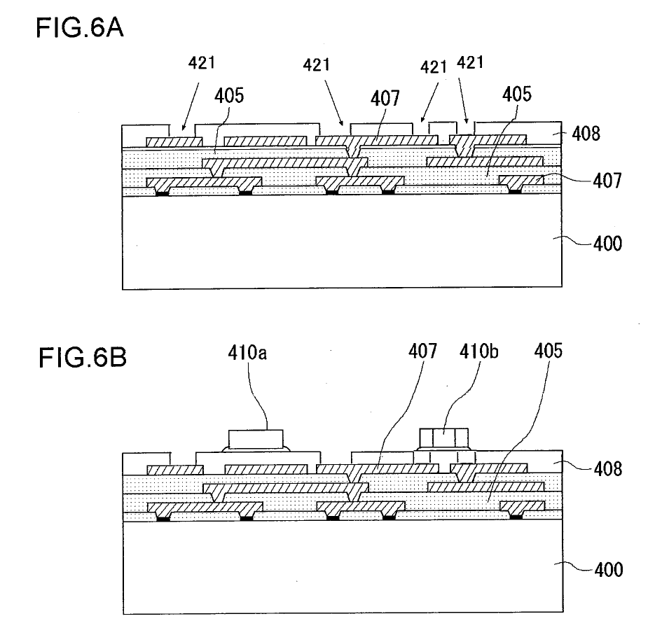

Now referring to FIG. 6A, after forming a solder resist layer 408 laser processing is executed to form a contact hole 421 in the solder resist layer 408. To constitute the solder resist layer 408, a filler-containing epoxy resin-based dielectric film is employed. To form the contact hole 421 laser processing is employed in this embodiment, while it is also possible to perform mechanical processing, chemical etching utilizing a chemical solution, or dry etching utilizing plasma. Then etching residue is removed by plasma irradiation. In this embodiment a plasma gas containing argon and oxygen is employed for the plasma processing.

Conditions of the plasma irradiation are to be appropriately determined according to a type of resin material to be used, so that a surface layer having the morphological characteristics and resin characteristics described earlier can be attained. Meanwhile, it is preferable not to apply a bias to the substrate. For example, it is preferable to set the following conditions.
Bias: Not applied
Plasma gas: Argon 10 to 20 sccm, oxygen 0 to 10 sccm

As a result of such plasma irradiation, etching residue on a surface of the interconnect 407 can be removed, and also a surface of the solder resist layer 408 can be modified so as to form a surface layer having the foregoing morphological characteristics and resin characteristics.

Thereafter, the elements 410a and 410b are mounted on the solder resist layer 408 as shown in FIG. 6B. A semiconductor element such as a transistor, a diode, an IC chip, etc. or a passive element such as a chip condenser, a chip resistance and so on may be used as the element 410. Also, a face-down semiconductor element as those used in a CSP or BGA etc. can also be mounted. In the structure shown in FIG. 6B, the element 410a is a bare semiconductor element (transistor chip) and the element 410b is a chip condenser. These elements are adhered to the solder resist layer 408. Under such state, the plasma processing is executed again. Conditions of the plasma irradiation are to be appropriately determined according to a type of resin material to be used, so that a surface layer having the morphological characteristics and resin characteristics described earlier can be attained. Meanwhile, it is preferable not to apply a bias to the substrate. For example, it is preferable to set the following conditions.
Bias: Not applied
Plasma gas: Argon 10 to 20 sccm, oxygen 0 to 10 sccm

As a result of such plasma irradiation, etching residue on a surface of the interconnect 407 can be removed, and also a surface of the solder resist layer 408 can be modified so as to form a surface layer having the foregoing morphological characteristics and resin characteristics.

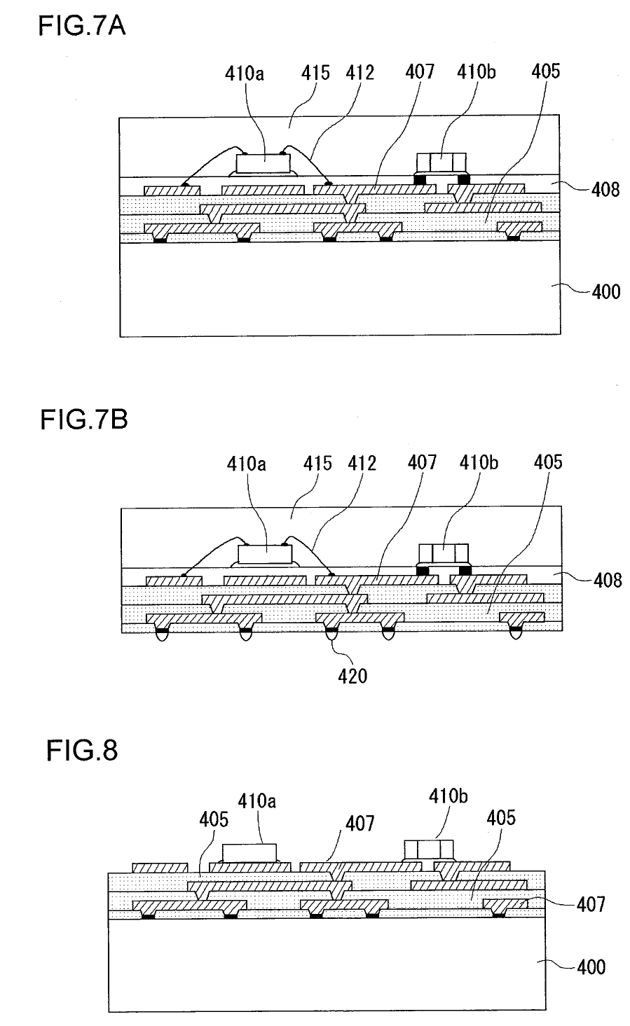

Then after connecting the element 410a with the interconnect 407 using the gold wiring 412 through the via hole already formed, these are molded in the molding resin 415. FIG. 7A shows a state where the molding has been completed. The step of molding the semiconductor element is simultaneously performed using a die with respect to a plurality of modules being formed on the metal foil 400. This step can be carried out by transfer molding, injection molding, potting or dipping process. Referring to a resin material, a thermosetting resin such as an epoxy resin can be employed for transfer molding or potting process, and a thermoplastic resin such as a polyimide resin, polyphenylenesulfide, etc. can be used for injection molding.

Referring now to FIG. 7B, the metal foil 400 is removed from the multilayer interconnect structure, to form solder balls 420 on a rear surface thereof. The removal of the metal foil 400 can be executed by polishing, grinding, etching, metal evaporation by laser, etc. In this embodiment the following method is adopted. An entire surface of the metal foil 400 is scraped by approx. 50 μm by a polishing or grinding apparatus, and chemical wet etching is executed over the remaining metal foil 400 for removal. It is also possible to remove an entirety of the metal foil 400 by wet etching. Through such steps, a rear surface of the interconnect 407 of the first layer is exposed on a rear face of the module opposite to the side where the semiconductor elements are mounted. As a result, the module thus manufactured according to this embodiment obtains a plane rear surface, which offers an advantage in processing that the module can horizontally move as it is owing to surface tension of the solder etc. and can easily self-align when mounting the semiconductor module. Then a conductive material such as a solder is placed on the exposed conductive coating 402 to form the solder balls 420, to thereby complete a formation process of the semiconductor module. Upon cutting the wafer by dicing, a semiconductor module chip can be obtained. The metal foil 400 serves as a supporting substrate until being removed as described above. The metal foil 400 also serves as an electrode in the electrolytic plating process for forming the interconnect 407. Further, the metal foil 400 can improve work efficiency when carrying the module to a die and mounting the module on the die, in the molding process using the molding resin 415. In this way, the semiconductor module having the structure shown in FIG. 4A is obtained.

Referring to such semiconductor module, since argon plasma processing is executed on the solder resist layer 408 for surface modification in the step of FIG. 6B, the interface adhesion between the solder resist layer 408 and the molding resin 415 is significantly improved. As a result, reliability of the semiconductor module can be substantially improved.

Meanwhile, a photopolymerizable thermosetting resin containing a polyfunctional oxetane compound or an epoxy compound may be employed for constituting the solder resist layer 408. As a result, since a plurality of crater-shaped recesses is formed on a surface of the solder resist layer 408 in addition to the minute projections, the adhesion is further upgraded.

Also, formation of projections and recesses on a surface of the solder resist layer 408 can be confirmed through analysis based on observation of an obliquely cut cross-section of the solder resist layer 408 through a scanning electronic microscope or the like.

Further, existence of projections and recesses on a surface not molded in the molding resin 415, such as an end portion of the solder resist layer 408, can be confirmed through analysis based on observation of such surface through a scanning electronic microscope or the like.

### Second Embodiment

In the first embodiment the element 410a and the element 410b are adhered by soldering to the solder resist layer 408, however it is also possible to adhere the element with an adhesive instead of by soldering. In this case the solder resist layer 408 may be omitted.

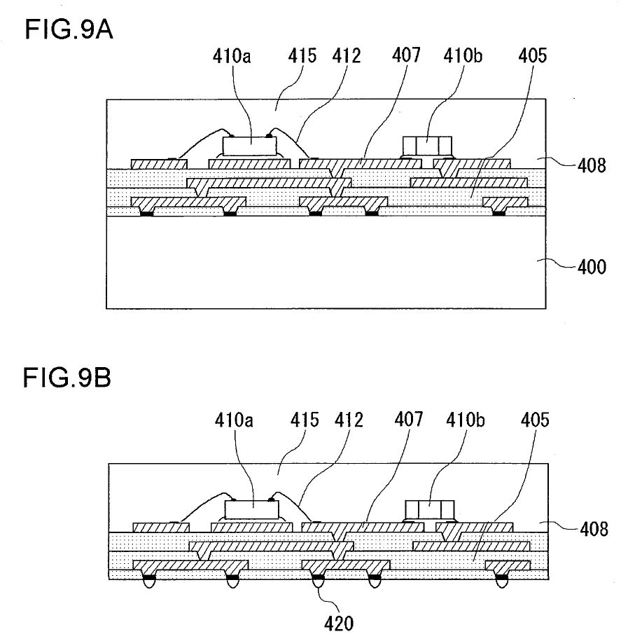

FIGS. 9A and 9B show a structure in which the elements are directly adhered to the interconnect without forming a solder resist layer. The multilayer interconnect structure itself is similar to that presented in the first embodiment. In this embodiment, the interlayer dielectric film 405 is constituted of an epoxy resin.

The above semiconductor module can be manufactured in the following steps. Firstly the steps up FIG. 5C are carried out. Then the element 410a and the element 410b are adhered with an adhesive as shown in FIG. 8. At this stage plasma processing is executed on the surface where the elements are provided. The plasma processing is to be executed in similar conditions to those of the first embodiment. As a result of the plasma irradiation a surface of the interconnect 407 is cleaned, thereby achieving secure connection of the elements 410a, 410b and the interconnect 407. Also, concurrently a surface of the interlayer dielectric film 405 is modified by the plasma processing, such that a surface layer having the foregoing morphological characteristics and resin characteristics is formed.

Then after connecting the element 410a with the interconnect 407 using the gold wiring 412, these are molded in the molding resin 415. At this stage the semiconductor module shown in FIG. 9A is obtained. Referring to this semiconductor module, since argon plasma processing is executed on the interlayer dielectric film 405 for surface modification in the step of FIG. 8, the interface adhesion between the interlayer dielectric film 405 and the molding resin 415 is significantly improved. As a result, reliability of the semiconductor module can be substantially improved.

Meanwhile, a photopolymerizable thermosetting resin containing a polyfunctional oxetane compound or an epoxy compound may be employed for constituting the interlayer dielectric film 405. As a result, since a plurality of crater-shaped recesses is formed on a surface of the interlayer dielectric film 405 in addition to the minute projections, the adhesion is further upgraded.

Also, formation of projections and recesses on a surface of the interlayer dielectric film 405 can be confirmed through analysis based on observation of an obliquely cut cross-section of the interlayer dielectric film 405 through a scanning electronic microscope or the like.

Further, existence of projections and recesses on a surface not molded in the molding resin 415, such as an end portion of the interlayer dielectric film 405, can be confirmed through analysis based on observation of such surface through a scanning electronic microscope or the like.

### Third Embodiment

In this embodiment, an element 502 is adhered to a substrate 506 via an adhesive 510, as shown in FIG. 15. The element 502 is electrically connected via a gold wire bonding 512 with a wiring 508. An element 504 is adhered to the element 502 via an adhesive 511, and the element 504 is electrically connected via a gold wire bonding 512 with a wiring 508. The element 502, the element 504 and the substrate 506 etc. are molded in the molding resin 415.

Accordingly, in case where adhesion between the element 502 and the substrate 506 is faulty, delamination of the element 502 may take place from that faulty portion, resulting in substantial degradation of reliability of the semiconductor module.

With an object to eliminate such problem, in this embodiment a surface of the substrate 506 that is to make contact with the adhesive 510, which is to make contact with a lower surface of the element 502, has been modified by plasma processing under similar conditions to those of the first and second embodiments. Specifically, minute projections and a plurality of crater-shaped recesses having a diameter of 100 nm or greater have been formed on a surface of the substrate 506 on which the interconnect 508 are located. Also, such surface of the substrate 506 has been processed such that a value of y/x becomes not less than 0.4, where x represents a detected intensity at a binding energy of 284.5 eV and y represents a detected intensity at a binding energy of 286 eV in an X-ray photoelectric spectroscopy spectrum.

Further, an exposed region of the substrate 506 that is to make contact with the molding resin 415 has been processed so as to form a contact angle of 30 degrees to 120 degrees with respect to pure water.

Meanwhile, a photopolymerizable thermosetting resin containing a polyfunctional oxetane compound or an epoxy compound may be employed for constituting the substrate 506. As a result, since a plurality of crater-shaped recesses is formed on a surface of the substrate 506 in addition to the minute projections, the adhesion is further upgraded.

Also, formation of projections and recesses on a surface of the substrate 506 can be confirmed through analysis based on observation of an obliquely cut cross-section of the substrate 506 through a scanning electronic microscope or the like.

Further, existence of projections and recesses on a surface not molded in the molding resin 415, such as an end portion of the substrate 506, can be confirmed through analysis based on observation of such surface through a scanning electronic microscope or the like.

As above, the preferable embodiments of the present invention have been described. However it is to be understood that the present invention is not limited to the foregoing embodiments, and that it is apparent to those skilled in the art that various modifications can be made within the scope of the present invention.

For example, while the foregoing embodiments refer to a semiconductor module, the present invention is applicable to a different module.

Also, in the foregoing embodiments the solder resist layer 408 is connected with the interconnect 407, however the solder resist layer 408 can be connected with another conductive material than the interconnect 407, for example a lead frame.

Further, in the foregoing embodiments the solder resist layer 408 is constituted of an insulating base material, however a base material other than an insulating base material can be employed.

### EXAMPLES

### Example 1

After sticking a dry film resist (Art. No. PDF300, manufactured by Nippon Steel Chemical Co., Ltd.) to a surface of a copper foil, patterning was executed to expose a portion of the copper foil surface. Then argon plasma processing was executed on an entire area including the exposed copper foil and the dry film resist surface. Two types of specimens have been made from different oxygen concentration in the plasma gas.
Bias: Not applied
Plasma gas: Specimen 1—Argon 10 sccm, oxygen 0 sccm
   Specimen 2—Argon 10 sccm, oxygen 10 sccm
RF power (W): 500
Pressure (Pa): 20
Duration (sec): 20

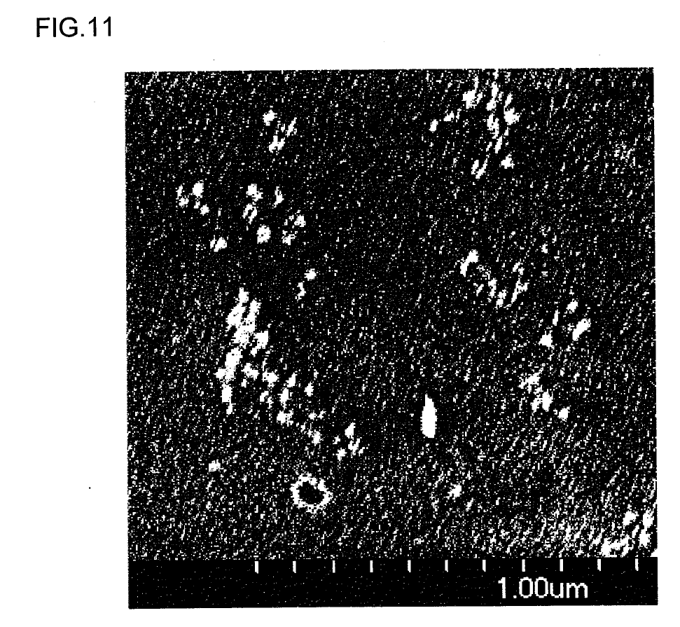

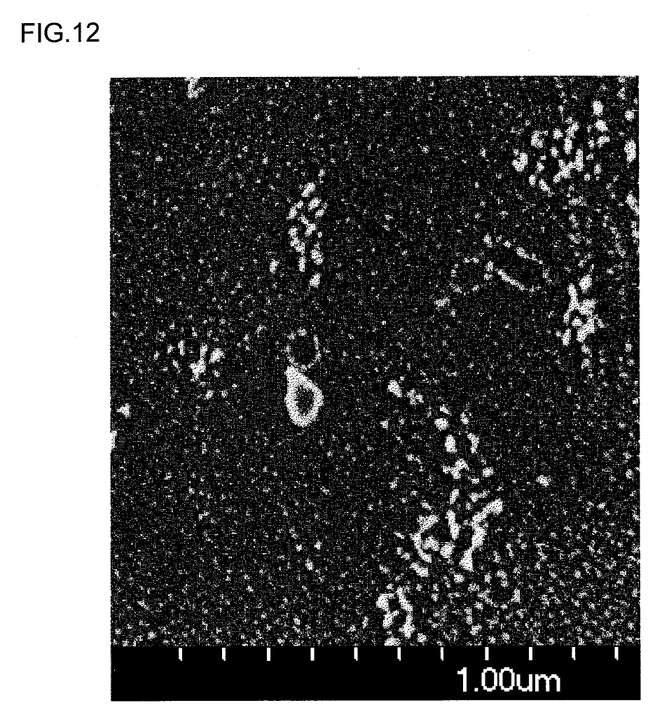

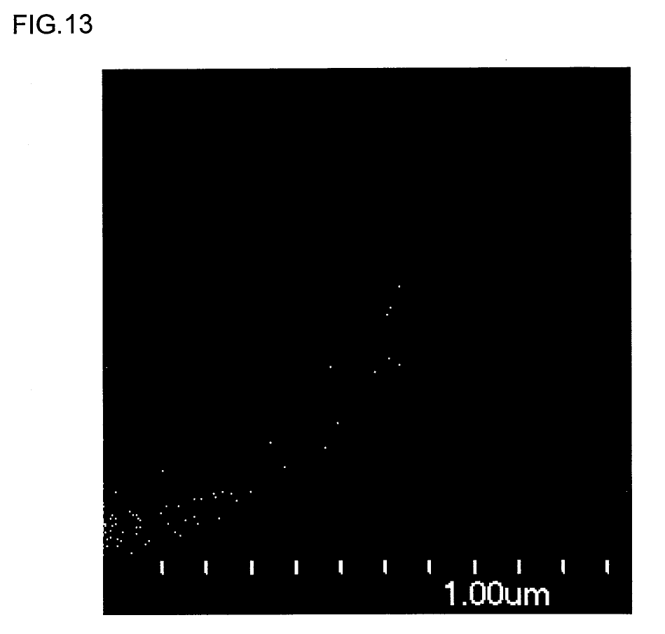

The dry film resist surface has been observed before and after the plasma irradiation through a scanning electronic microscope. The results are shown in FIGS. 11 to 13. FIG. 11 shows the appearance of the specimen 1, FIG. 12 that of the specimen 2, and FIG. 13 the appearance before plasma irradiation. It has been proven that a multitude of minute projections is formed on the resin surface by plasma irradiation. Then an average diameter and density of the minute projections have been measured based on the image data obtained from the observation through the scanning electronic microscope. The density has been worked out through measuring the number of the minute projections along a 1 μm-long line (line density) and calculating the square of such number. The results are given below.

Specimen 1
Average diameter: 4 nm
Number density: 1.2×10³ pieces/μm²

Specimen 2
Average diameter: 4 nm
Number density: 1.6×10³ pieces/μm²

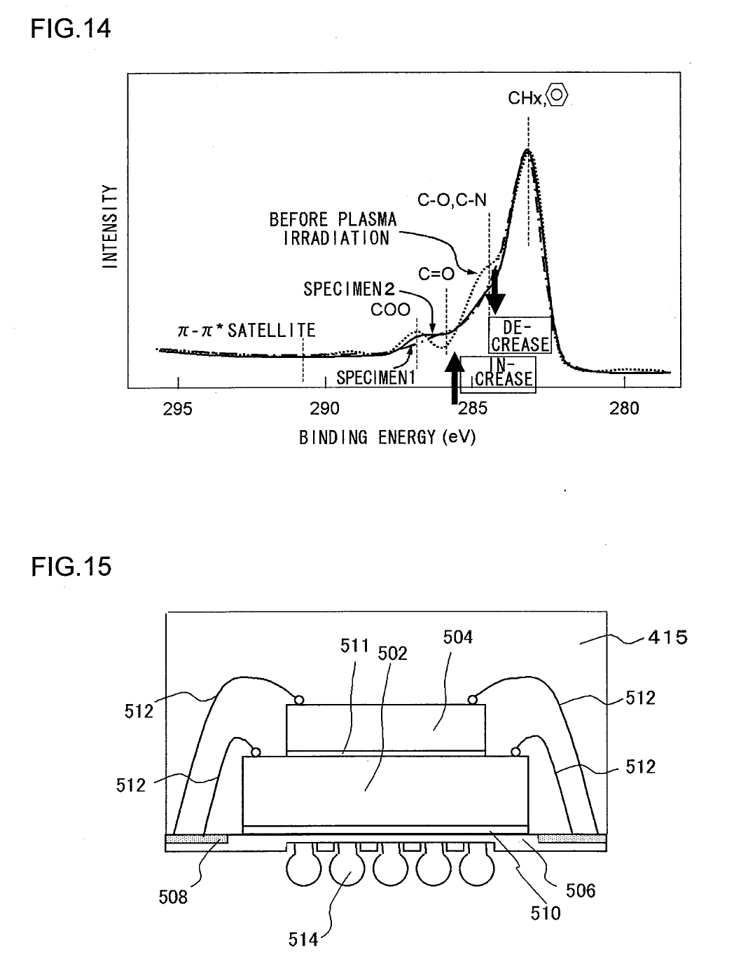

Thereafter, X-ray photoelectron spectroscopy has been executed with respect to the specimens 1 and 2. The result is shown in FIG. 14. In FIG. 14, data of the film surface before the argon plasma irradiation is also shown as a reference, in addition to data of the specimens 1 and 2. In view of FIG. 14 it is evident that an intensity originating from a C═O bond at 286 eV is increasing while an intensity originating from a C—O or C—N bond at 284.5 eV is decreasing because of the plasma irradiation. A value of y/x of the module according to this example, where x represents an intensity originating from a C—O or C—N bond at 284.5 eV and y represents an intensity originating from a C═O bond at 286 eV, has proved to be approx. 0.44 with both specimens 1 and 2.

Finally a contact angle has been measured with respect to the specimens 1 and 2. A droplet of pure water was dropped on the film surface, and form of the droplet has been observed through a magnifier to measure the contact angle. The measurement of the contact angle was carried out two days after making up the specimens. The contact angle values are given below. In view of these values, it is proven through the specimens 1 and 2 constituted of a dry film resist (Art. No. PDF300, manufactured by Nippon Steel Chemical Co., Ltd.), that it is preferable that a contact angle is in a range of 30 to 70 degrees.
Specimen 1: 52.0 degrees
Specimen 2: 53.6 degrees

A semiconductor module has been made up through the steps described in the first embodiment, utilizing a similar film to the specimens 1 and 2 and executing a similar plasma processing to that applied to the same specimens. Accordingly such semiconductor module is provided with the dry film resist according to the specimens 1 and 2 serving as the solder resist layer, on a surface of which a semiconductor element is mounted. Upon evaluating this semiconductor module, the module has proved to have excellent heat cycle resistance, and also has achieved an excellent result from a pressure cooker test.

### Example 2

After sticking a dry film resist (Art. No. AUS402,manufactured by Taiyo Ink Mfg. Co., Ltd.) to a surface of a copper foil, patterning was executed to expose a portion of the copper foil surface. Then argon plasma processing was executed on an entire area including the exposed copper foil and the dry film resist surface.

Here, a photopolymerizable thermosetting resin containing a polyfunctional oxetane compound or an epoxy compound is employed for constituting the dry film resist (Art. No. AUS402, manufactured by Taiyo Ink Mfg. Co., Ltd.); therefore the film surface is provided with crater-shaped recesses.
Bias: Not applied
Plasma gas: Argon 10 sccm, oxygen 0 sccm
RF power (W): 500
Pressure (Pa): 20
Duration (sec): Specimen 3—20 seconds
   Specimen 4—60 seconds

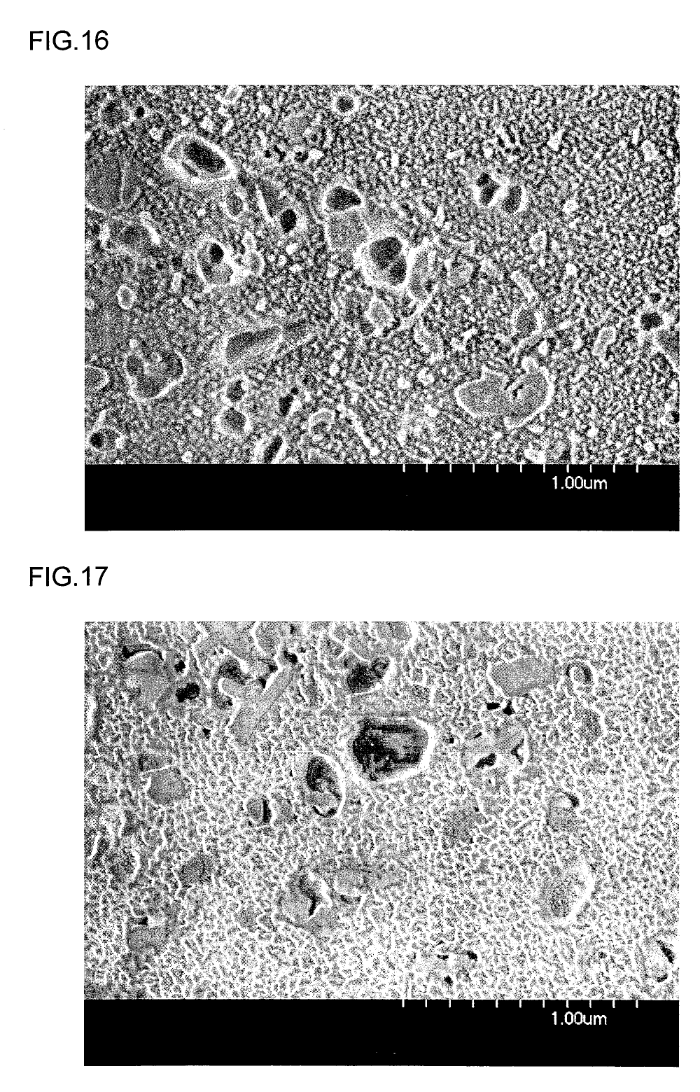

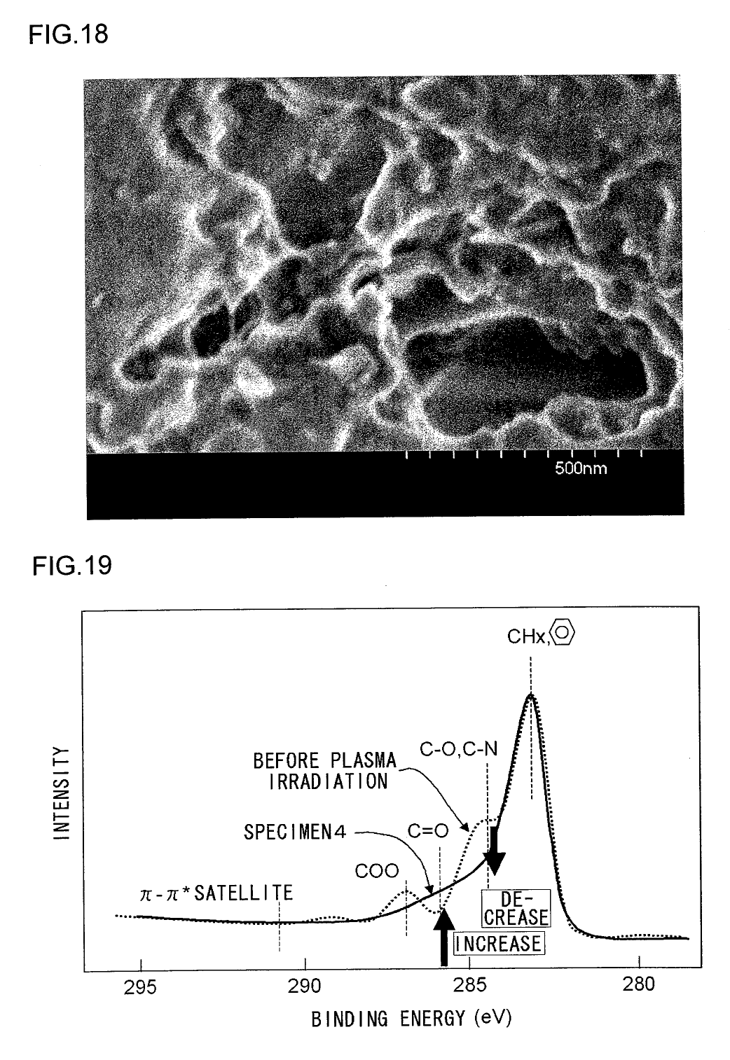

The dry film resist surface has been observed before and after the plasma irradiation through a scanning electronic microscope. The results are shown in FIGS. 16 to 18. FIG. 16 shows the appearance of the specimen 3, FIG. 17 that of the specimen 4, and FIG. 18 the appearance without plasma irradiation. It has been proven that a multitude of minute projections is formed on the resin surface by plasma irradiation. Then an average diameter and density of the minute projections have been measured based on the image data obtained from the observation through the scanning electronic microscope. The density has been worked out through measuring the number of the minute projections along a 1 μm-long line (line density) and calculating the square of such number. The results are given below.

Specimen 3
Average diameter: 4 nm
Number density: 2×10³ pieces/μm²

Specimen 4
Average diameter: 4 nm
Number density: 2×10³ pieces/μm²

In addition, existence of a plurality of crater-shaped recesses having a diameter of 100 nm or greater has been confirmed with respect to both specimens 3 and 4.

Thereafter, X-ray photoelectron spectroscopy has been executed with respect to these specimens. The result is shown in FIG. 19. In FIG. 19, data of the film surface before the argon plasma irradiation is also shown as a reference, in addition to data of the specimen 4. In view of FIG. 19 it is evident that an intensity originating from a C═O bond at 286 eV is increasing while an intensity originating from a C—O or C—N bond at 284.5 eV is decreasing because of the plasma irradiation. A value of y/x of the module according to this example, where x represents an intensity originating from a C—O or C—N bond at 284.5 eV and y represents an intensity originating from a C═O bond at 286 eV, has proved to be approx. 0.4.

Finally a contact angle has been measured with respect to these specimens. A droplet of pure water was dropped on the film surface, and form of the droplet has been observed through a magnifier to measure the contact angle. The measurement of the contact angle was carried out two days after making up the specimens. The contact angle values are given below.
Specimen 3: 80 degrees
Specimen 4: 105 degrees

A semiconductor module has been made up through the steps described in the first embodiment, utilizing a similar film to the above specimens and executing a similar plasma processing to that applied to the same specimens. Accordingly such semiconductor module is provided with the dry film resist according to the specimens serving as the solder resist layer, on a surface of which a semiconductor element is mounted. Upon evaluating this semiconductor module, the module has proved to have excellent heat cycle resistance, and also has achieved an excellent result from a pressure cooker test.

1-17. (canceled)

18. A method of manufacturing a semiconductor module comprising an insulating base material provided with a conductor circuit, a semiconductor element formed on said insulating base material, and an insulator disposed in contact with said insulating base material and said semiconductor element, wherein said insulating base material is provided with minute projections on a surface thereof that is in contact with said insulator, the method comprising:
applying plasma processing with a plasma gas containing an inert gas to a surface of said insulating base material provided with a conductor circuit without applying a bias to said insulating base material; and
forming a semiconductor element and an insulator in contact with said semiconductor element on said insulating base material.

19. A method of manufacturing a semiconductor module comprising an insulating base material provided with a conductor circuit, a semiconductor element formed on said insulating base material, and an insulator disposed in contact with said insulating base material and said semiconductor element, wherein a value of y/x is not less than 0.4, where x represents a detected intensity at a binding energy of 284.5 eV and y represents a detected intensity at a binding energy of 286 eV, by an X-ray photoelectric spectroscopy spectrum in the proximity of a surface of said insulating base material that is in contact with said insulator, the method comprising:
applying plasma processing with a plasma gas containing an inert gas to a surface of said insulating base material provided with a conductor circuit without applying a bias to said insulating base material; and
forming a semiconductor element and an insulator in contact with said semiconductor element on said insulating base material.

20. A method of manufacturing a semiconductor module comprising an insulating base material provided with a conductor circuit, a semiconductor element formed on said insulating base material, and an insulator disposed in contact with said insulating base material and said semiconductor element, wherein an exposed region of said insulating base material in contact with said insulator makes a contact angle of 30 degrees to 120 degrees with respect to pure water, the method comprising:
applying plasma processing with a plasma gas containing an inert gas to a surface of said insulating base material provided with a conductor circuit without applying a bias to said insulating base material; and
forming a semiconductor element and an insulator in contact with said semiconductor element on said insulating base material.

21. A method of manufacturing a semiconductor module set forth in claim 10, comprising an insulating base material provided with a conductor circuit, a semiconductor element formed on said insulating base material, and an insulator disposed in contact with said insulating base material and said semiconductor element, wherein said insulating base material is constituted essentially of a photopolymerizable thermosetting resin containing a polyfunctional oxetane compound or an epoxy compound, the method comprising:
applying plasma processing with a plasma gas containing an inert gas to a surface of said insulating base material provided with a conductor circuit without applying a bias to said insulating base material; and
forming a semiconductor element and an insulator in contact with said semiconductor element on said insulating base material.

22. A method of manufacturing a module comprising a base material; an element formed on said base material; and an insulator disposed in contact with said base material and said element, wherein said base material is provided with minute projections on a surface thereof that is in contact with said insulator, the method comprising:
applying plasma processing with a plasma gas containing an inert gas to a surface of said base material without applying a bias to said base material; and
forming an element and an insulator in contact with said element on said base material.
